(19) United States
(12) Patent Application Publication
(10) Pub. No.: US 2018/0067330 A1
(43) Pub. Date: Mar. 8, 2018

(54) PROCESSING DEVICE AND COLLIMATOR

(71) Applicant: Kabushiki Kaisha Toshiba, Minato-ku (JP)

(72) Inventors: Takahiro TERADA, Yokohama (JP); Shiguma KATO, Yokohama (JP); Yoshinori TOKUDA, Yokohama (JP); Masakatsu TAKEUCHI, Obu (JP); Yasuhiro AOYAMA, Yokkaichi (JP)

(73) Assignee: Kabushiki Kaisha Toshiba, Minato-ku (JP)

(21) Appl. No.: 15/524,090

(22) PCT Filed: Dec. 19, 2016
(86) PCT No.: PCT/JP2016/087818

§ 371 Date: May 3, 2017

(30) Foreign Application Priority Data
Mar. 14, 2016 (JP) 2016-050216

(51) Int. Cl. G02B 27/30; H01L 21/203; H01L 21/285

(52) U.S. Cl. CPC G02B 27/30; H01L 21/285; H01L 21/203

(57) ABSTRACT

According to one embodiment, a processing device comprises a substance arrangement part, a generating source arrangement part, and a collimator. A substance is arranged on the substance arrangement part. The generating source arrangement part is arranged at a position separated away from the substance arrangement part. A particle generating source that is able to emit a particle to the substance is arranged on the generating source arrangement part. The collimator is configured to be arranged between the substance arrangement part and the generating source arrangement part. The collimator includes: a frame; and a first rectifying part that includes a plurality of first walls and a plurality of first through holes formed with the first walls and extending in a first direction from the generating source arrangement part toward the substance arrangement part, the collimator configured to be removably attached to the frame.

### CROSS-REFERENCE TO RELATED APPLICATIONS

This application is national stage application of International Application No. PCT/JP2016/087818, filed Dec. 19, 2016, which designates the United States, incorporated herein by reference, and which claims priority from Japanese Patent Application No. 2016-050216, filed Mar. 14, 2016, the entire contents of which are incorporated herein by reference.

### FIELD

An embodiment described herein relates generally to a processing device and a collimator.

### BACKGROUND

For example, sputtering devices that deposit metal on a semiconductor wafer include a collimator for aligning directions of metal particles to be deposited. The collimator includes walls forming a large number of through holes, allows passage of particles flying in a direction substantially perpendicular to a substance to be processed such as a semiconductor wafer, and blocks particles flying in an oblique direction.

A range of directions of deposited particles is determined depending on a shape of the collimator. Thus, when the range of the directions of the deposited particles is changed, the collimator is replaced.

### BRIEF DESCRIPTION OF DRAWINGS

FIG. 1 is a cross-sectional view schematically illustrating a sputtering device according to a first embodiment.

FIG. 2 is a plan view schematically illustrating a collimator according to the first embodiment.

FIG. 3 is a cross-sectional view schematically illustrating the collimator according to the first embodiment.

FIG. 4 is a cross-sectional view schematically illustrating a base component according to the first embodiment along the line F4-F4 in FIG. 3.

FIG. 5 is a cross-sectional view schematically illustrating the collimator including two collimation components according to the first embodiment.

FIG. 6 is a cross-sectional view schematically illustrating the collimator including another collimation component according to the first embodiment.

FIG. 7 is a cross-sectional view schematically illustrating the collimator from which the collimation component is removed according to the first embodiment.

FIG. 8 is a plan view schematically illustrating the collimator in which the collimation component is rotated according to the first embodiment.

FIG. 9 is a plan view schematically illustrating a collimator according to a second embodiment.

FIG. 10 is a plan view schematically illustrating a collimator in which a collimation component is moved according to the second embodiment.

FIG. 11 is a cross-sectional view schematically illustrating a sputtering device according to a third embodiment.

FIG. 12 is a cross-sectional view schematically illustrating a collimator according to the third embodiment.

FIG. 13 is a plan view schematically illustrating a collimator according to a first modification of the third embodiment.

FIG. 14 is a cross-sectional view schematically illustrating a collimator according to a second modification of the third embodiment.

### DETAILED DESCRIPTION

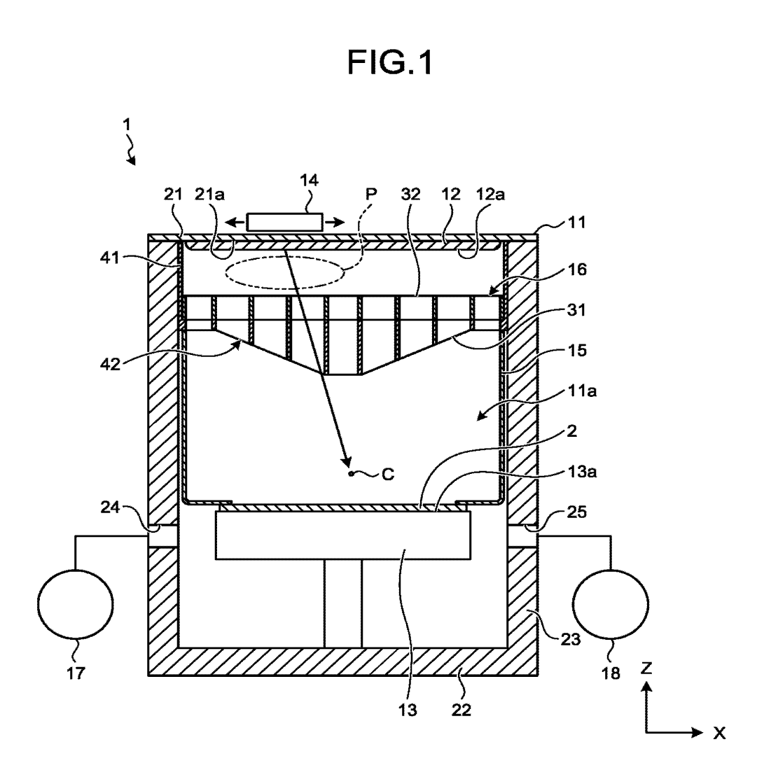

The following describes a first embodiment with reference to FIGS. 1 to 8. In this description, basically, a vertically upward direction is defined as an upward direction, and a vertically downward direction is defined as a downward direction. In this description, a plurality of expressions may be used for a component according to the embodiment and description of the component. Other expressions that are not described herein may be used for the component and the description expressed in a plurality of ways. Other expressions that are not described herein may be used for a component and description that are not expressed in a plurality of ways.

FIG. 1 is a cross-sectional view schematically illustrating a sputtering device 1 according to a first embodiment. The sputtering device 1 is an example of a processing device, and may be referred to as a semiconductor manufacturing device, a manufacturing device, a machining device, or a device, for example.

The sputtering device 1 is a device for performing magnetron sputtering, for example. The sputtering device 1 performs deposition using metal particles on a surface of a semiconductor wafer 2, for example. The semiconductor wafer 2 is an example of a substance, and may be referred to as an object, for example. The sputtering device 1 may perform deposition on another object, for example.

The sputtering device 1 includes a chamber 11, a target 12, a stage 13, a magnet 14, a shielding member 15, a collimator 16, a pump 17, and a tank 18. The target 12 is an example of a particle generating source. The collimator 16 can be referred to as a shielding component, a rectifying component, or a direction adjusting component, for example.

As illustrated in the drawings, the X-axis, the Y-axis, and the Z-axis are defined herein. The X-axis, the Y-axis, and the Z-axis are orthogonal to each other. The X-axis is along a width of the chamber 11. The Y-axis is along a depth (length) of the chamber 11. The Z-axis is along a height of the chamber 11. The following description is given assuming that the Z-axis is along a vertical direction. The Z-axis of the sputtering device 1 may obliquely intersect with the vertical direction.

The chamber 11 is formed in a box shape that can be sealed. The chamber 11 includes an upper wall 21, a bottom wall 22, a side wall 23, an ejection port 24, and an introduction port 25. The upper wall 21 may also be referred to as a backing plate, an attachment part, or a holding part, for example.

The upper wall 21 and the bottom wall 22 are arranged to be opposed to each other in a direction along the Z-axis (vertical direction). The upper wall 21 is positioned above the bottom wall 22 with a predetermined gap therebetween. The side wall 23 is formed in a tubular shape extending in a direction along the Z-axis to connect the upper wall 21 with the bottom wall 22.

A processing chamber 11a is arranged inside the chamber 11. The processing chamber 11a can also be referred to as the inside of a container. Inner faces of the upper wall 21, the bottom wall 22, and the side wall 23 form the processing chamber 11a. The processing chamber 11a can be closed airtightly. In other words, the processing chamber 11a can be sealed. An airtightly closed state means a state in which gas does not move between the inside and the outside of the processing chamber 11a, and the ejection port 24 and the introduction port 25 may be opened in the processing chamber 11a.

The target 12, the stage 13, the shielding member 15, and the collimator 16 are arranged in the processing chamber 11a. In other words, the target 12, the stage 13, the shielding member 15, and the collimator 16 are housed in the chamber 11. The target 12, the stage 13, the shielding member 15, and the collimator 16 may be partially positioned outside the processing chamber 11a.

The ejection port 24 is opened in the processing chamber 11a, and connected to the pump 17. Examples of the pump 17 include a dry pump, a cryopump, or a turbo molecular pump. When the pump 17 sucks the gas in the processing chamber 11a through the ejection port 24, air pressure in the processing chamber 11a can be lowered. The pump 17 can evacuate the processing chamber 11a.

The introduction port 25 is opened in the processing chamber 11a, and connected to the tank 18. The tank 18 houses an inert gas such as an argon gas. The argon gas may be introduced into the processing chamber 11a from the tank 18 through the introduction port 25. The tank 18 includes a valve that can stop introduction of the argon gas.

The target 12 is, for example, a disk-shaped metal plate used as a particle generating source. The target 12 may be formed in another shape. In this embodiment, the target 12 is made of copper, for example. The target 12 may be made of another material.

The target 12 is attached to an attachment face 21a of the upper wall 21 of the chamber 11. The upper wall 21 as a backing plate is used as a coolant for the target 12 and an electrode. The chamber 11 may include a backing plate as a component different from the upper wall 21.

The attachment face 21a of the upper wall 21 is an inner face of the upper wall 21 that faces a negative direction (downward direction) along the Z-axis and is formed to be substantially flat. The target 12 is arranged on the attachment face 21a. The upper wall 21 is an example of a generating source arrangement part. The generating source arrangement part is not limited to an independent member or component, and may foe a specific position on a certain member or component.

The negative direction along the Z-axis is a direction opposite to a direction pointed by the arrow of the Z-axis. The negative direction along the Z-axis is a direction from the attachment face 21a of the upper wall 21 toward a placement face 13a of the stage 13, which is an example of a first direction. The direction along the Z-axis and the vertical direction include the negative direction along the Z-axis and a positive direction along the Z-axis (the direction pointed by the arrow of the Z-axis).

The target 12 includes a lower face 12a. The lower face 12a is a substantially fiat surface facing downward. When voltage is applied to the target 12, the argon gas introduced into the chamber 11 is ionized, and plasma P is generated. FIG. 1 illustrates the plasma P by a two-dot chain line.

The magnet 14 is positioned outside the processing chamber 11a. The magnet 14 is, for example, an electromagnet or a permanent magnet. The magnet can move along the upper wall 21 and the target 12. The upper wall 21 is positioned between the target 12 and the magnet 14. The plasma P is generated near the magnet 14. Thus, the target 12 is positioned between the magnet 14 and the plasma P.

When an argon ion in the plasma P collides with the target 12, a particle C of a deposition material included in the target 12 flies from the lower face 12a of the target 12, for example. In other words, the target 12 can emit the particle C. In the present embodiment, the particle C includes a copper ion, a copper atom, and a copper molecule.

Directions in which particles C fly from the lower face 12a of the target 12 are distributed in accordance with a cosine law (Lambert's cosine law). That is, the number of the particles C flying from a certain point on the lower face 12a is the largest in a normal direction (vertical direction) of the lower face 12a. The number of the particles C flying in a direction inclined by an angle θ with respect to (obliquely intersecting with) the normal direction is substantially proportional to a cosine (cos θ) of the number of the particles C flying in the normal direction.

The particle C is an example of the particle according to the present embodiment, and is a minute particle of the deposition material included in the target 12. The particles may be various particles constituting a substance or an energy ray such as a molecule, an atom, an ion, an atomic nucleus, an electron, an elementary particle, vapor (a vaporized substance), and an electromagnetic wave (a photon).

The stage 13 is arranged on the bottom wall 22 of the chamber 11. The stage 13 is arranged to be separated away from the upper wall 21 and the target 12 in a direction along the Z-axis. The stage 13 includes a placement face 13a. The placement face 13a of the stage 13 supports the semiconductor wafer 2. The semiconductor wafer 2 is formed in a disk-shape, for example. The semiconductor wafer 2 may be formed in another shape.

The placement face 13a of the stage 13 is a substantially flat surface facing upward. The placement face 13a is arranged to foe separated away from the attachment face 21a of the upper wall 21 in the direction along the Z-axis, and faces the attachment face 21a. The semiconductor wafer 2 is arranged on the placement face 13a. The stage 13 is an example of a substance arrangement part. The substance arrangement part is not limited to an independent member or component, and may be a specific position on a certain member or component.

The stage 13 can move in the direction along the Z-axis, that is, the vertical direction. The stage 13 includes a heater, and can heat the semiconductor wafer 2 arranged on the placement face 13a. The stage 13 is also used as an electrode.

The shielding member 15 is formed in a substantially tubular shape. The shielding member 15 covers part of the side wall 23 and a gap between the side wall 23 and the semiconductor wafer 2. The shielding member 15 may hold the semiconductor wafer 2. The shielding member 15 prevents the particle C emitted from the target 12 from adhering to the bottom wall 22 and the side wall 23.

The collimator 16 is arranged between the attachment face 21a of the upper wall 21 and the placement face 13a of the stage 13 in the direction along the Z-axis. In other words, the collimator 16 is arranged between the target 12 and the semiconductor wafer 2 in the direction along the Z-axis (vertical direction). The collimator 16 is attached to the side wall 23 of the chamber 11, for example. The collimator 16 may be supported by the shielding member 15.

The collimator 16 is insulated from the chamber 11. For example, an insulating member is interposed between the collimator 16 and the chamber 11. Additionally, the collimator 16 is insulated from the shielding member 15.

In the direction along the Z-axis, a distance between the collimator 16 and the attachment face 21a of the upper wall 21 is shorter than a distance between the collimator 16 and the placement face 13a of the stage 13. In other words, the collimator 16 is closer to the attachment face 21a of the upper wall 21 than to the placement face 13a of the stage 13. The arrangement of the collimator 16 is not limited thereto.

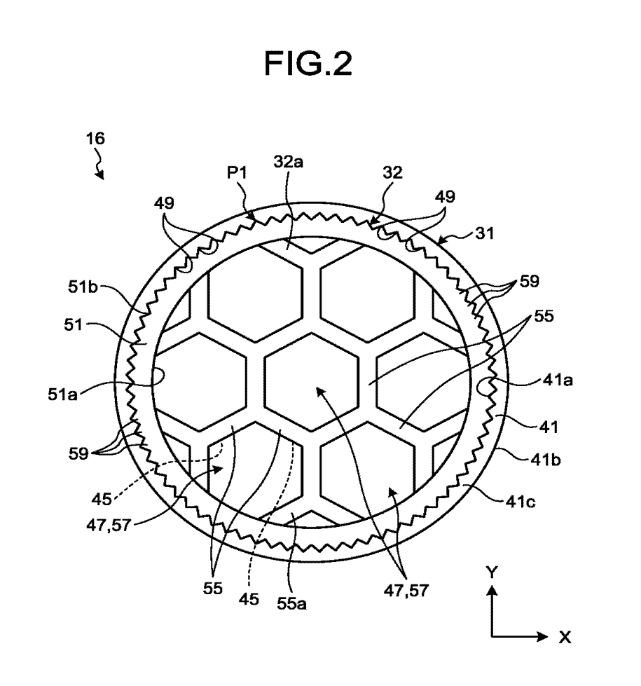

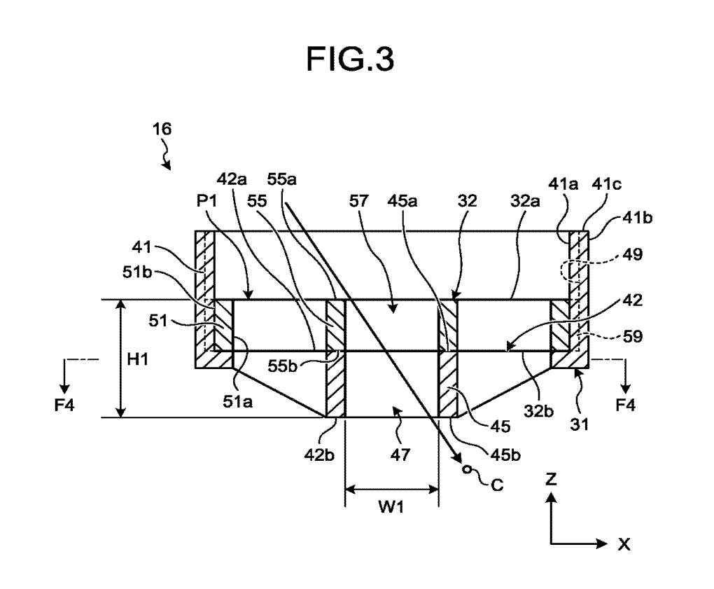

FIG. 2 is a plan view schematically illustrating the collimator 16 according to the first embodiment. FIG. 3 is a cross-sectional view schematically illustrating the collimator 16 according to the first embodiment. As illustrated in FIG. 3, the collimator 16 includes a base component 31 and a collimation component 32. The collimation component 32 is an example of a first-rectifying part.

The base component 31 is made of, for example, aluminum. The base component 31 may be made of another material. The base component 31 includes a frame 41 and a rectifying part 42. For example, the frame 41 may also be referred to as an outer edge part, a holding part, a supporting part, or a wall. The rectifying part 42 is an example of a second rectifying part.

The frame 41 is a wall formed in a substantially cylindrical shape extending in the direction along the Z-axis. The shape of the frame 41 is not limited thereto, and the frame 41 may be formed in another shape such as a rectangle. The frame 41 includes an inner peripheral face 41a and an outer peripheral face 41b.

The inner peripheral face 41a of the frame 41 is a curved face facing a radial direction of the cylindrical frame 41, and faces a center axis of the tubular frame 41. The outer peripheral face 41b is positioned on the opposite side of the inner peripheral face 41a. An area of a portion surrounded by the outer peripheral face 41b of the frame 41 on an X-Y plane is larger than a cross-sectional area of the semiconductor wafer 2.

As illustrated in FIG. 1, the frame 41 covers part of the side wall 23. Between the upper wall 21 and the stage 13 in the direction along the Z-axis, the side wall 23 is covered with the shielding member 15 and the frame 41 of the collimator 16. The frame 41 prevents the particle C emitted from the target 12 from adhering to the side wall 23.

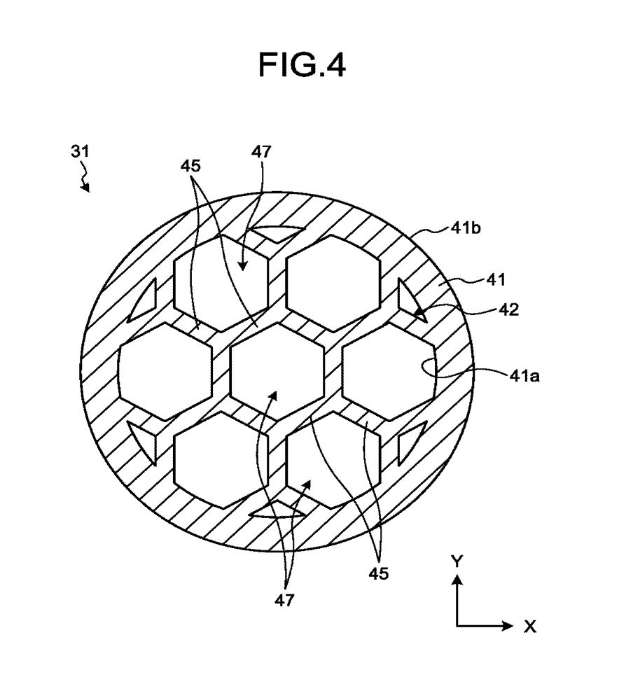

FIG. 4 is a cross-sectional view schematically illustrating the base component 31 according to the first embodiment along the line F4-F4 in FIG. 3. As illustrated in FIG. 4, the rectifying part 42 is arranged inside the tubular frame 41 on the X-Y plane. The rectifying part 42 is connected to the inner peripheral face 41a of the frame 41. The frame 41 and the rectifying part 42 are integrally formed. In other words, the rectifying part 42 is fixed to the inside of the frame 41. The rectifying part 42 may be a component independent of the frame 41.

As illustrated in FIG. 1, the rectifying part 42 is arranged between the attachment face 21a of the upper wall 21 and the placement face 13a of the stage 13. The rectifying part 42 is separated away from the upper wall 21 and from the stage 13 in the direction along the Z-axis. As illustrated in FIG. 4, the rectifying part 42 includes a plurality of first wall parts 45. The first wall parts 45 are examples of a plurality of second walls, and may also be referred to as plates or shielding parts, for example.

In the rectifying part 42, the first wall parts 45 form a plurality of first openings 47 arranged in substantially parallel with each other. The first openings 47 are examples of a plurality of second through holes. Each of the first openings 47 is a hexagonal hole extending in the direction along the Z-axis (vertical direction). In other words, the first wall parts 45 form an aggregate (honeycomb structure) of a plurality of hexagonal tubes in which the first opening 47 is formed. The first opening 47 extending in the direction along the Z-axis can allow passage of a substance such as the particle C moving in the direction along the Z-axis. The first opening 47 may be formed in another shape.

As illustrated in FIG. 3, the rectifying part 42 includes an upper end part 42a and a lower end part 42b. The upper end part 42a is one end of the rectifying part 42 in the direction along the Z-axis, and faces the target 12 and the attachment face 21a of the upper wall 21. The lower end part 42b is the other end of the rectifying part 42 in the direction along the Z-axis, and faces the semiconductor wafer 2 supported by the stage 13 and the placement face 13a of the stage 13.

The first opening 47 is arranged from the upper end part 42a to the lower end part 42b of the rectifying part 42. That is, the first opening 47 is a hole that opens toward the target 12, and opens toward the semiconductor wafer 2 supported by the stage 13.

Each of the first wall parts 45 is a substantially rectangular (quadrangle) plate extending in the direction along the Z-axis. The first wall part 45 may extend, for example, in a direction obliquely intersecting with the direction along the Z-axis. The first wall part 45 includes an upper end face 45a and a lower end face 45b.

The upper end face 45a of the first wall part 45 is one end of the first wall part 45 in the direction along the Z-axis, and faces the target 12 and the attachment face 21a of the upper wall 21. The upper end face 45a of each of the first wall parts 45 forms the upper end part 42a of the rectifying part 42.

The upper end part 42a of the rectifying part 42 is formed to be substantially flat. For example, the upper end part 42a may be depressed like a curved face with respect to the target 12 and the attachment face 21a of the upper wall 21. In other words, the upper end part 42a may be curved to be separated away from the target 12 and the attachment face 21a of the upper wall 21.

The lower end face 45b of the first wall part 45 is the other end of the first wall part 45 in the direction along the Z-axis, and faces the semiconductor wafer 2 supported by the stage 13 and the placement face 13a of the stage 13. The lower end face 45b of each of the first wall parts 45 forms the lower end part 42b of the rectifying part 42.

The lower end part 42b of the rectifying part 42 projects toward the semiconductor wafer 2 supported by the stage 13 and the placement face 13a of the stage 13. In other words, the lower end part 42b of the rectifying part 42 may become closer to the stage 13 as being separated away from the frame 41. The lower end part 42b of the rectifying part 42 may be formed in another shape.

The upper end part 42a and the lower end part 42b of the rectifying part 42 have different shapes. Thus, the rectifying part 42 includes a plurality of first wall parts 45 having lengths different from each other in the vertical direction. The first wall parts 45 may have the same length in the direction along the Z-axis.

As illustrated in FIG. 2, a plurality of grooves 49 are arranged on the inner peripheral face 41a of the frame 41. The groove 49 is an example of a first holding part. Each of the grooves 49 extends in the direction along the Z-axis. The grooves 49 extend from the upper end part 42a of the rectifying part 42 to an upper end 41c of the frame 41. The groove 49 opens in a positive direction along the Z-axis at the upper end 41c of the frame 41. The upper end 41c is one end of the frame 41 in the direction along the Z-axis, and faces the upper wall 21.

The grooves 49 are arranged in a circumferential direction of the tubular frame 41. The circumferential direction of the frame 41 is a direction rotating about the center axis of the frame 41. The grooves 49 are arranged on the entire inner peripheral face 41a of the frame 41 in the circumferential direction of the frame 41. For example, the grooves 49 may be arranged at intervals in the circumferential direction of the frame 41.

For example, the collimation component 32 is made of aluminum similarly to the base component 31. The collimation component 32 may be made of another material, or may be made of a material different from the material of the base component 31.

As illustrated in FIG. 1, the collimation component 32 is arranged between the attachment face 21a of the upper wall 21 and the placement face 13a of the stage 13. The collimation component 32 is separated away from the upper wall 21 and from the stage 13 in the direction along the Z-axis.

As illustrated in FIG. 2, the colligation component 32 includes a frame part 51 and a plurality of second wall parts 55. For example, the frame part 51 may also be referred to as an outer edge part, a holding part, a supporting part, or a wall. The second wall parts 55 are examples of a plurality of first walls, and can also be referred to as plates or shielding parts, for example.

The frame part 51 is a wall formed in a substantially cylindrical shape extending in the direction along the Z-axis. The shape of the frame part 51 is not limited thereto, and the frame part 51 may foe formed in another shape such as a rectangle. The frame part 51 includes an inner peripheral face 51a and an outer peripheral face 51b.

The inner peripheral face 51a of the frame part 51 is a curved face facing a radial direction of the cylindrical frame part 51, and faces a center axis of the tubular frame part 51. The outer peripheral face 51b is positioned on the opposite side of the inner peripheral face 51a. An area of a portion surrounded by the outer peripheral face 51b of the frame part 51 on the X-Y plane is larger than the cross-sectional area of the semiconductor wafer 2.

The frame part 51 is arranged inside the frame 41 of the base component 31. An outer diameter of the frame part 51 is smaller than an inner diameter of the frame 41. The frame part 51 covers part of the inner peripheral face 41a of the frame 41. The frame part 51 prevents the particle C emitted from the target 12 from adhering to part of the inner peripheral face 41a of the frame 41.

As illustrated in FIG. 3, a plurality of second wall parts 55 are arranged inside the tubular frame part 51 on the X-Y plane. The second wall parts 55 are connected to the inner peripheral face 51a of the frame part 51. The frame part 51 and the second wall parts 55 are integrally formed. In other words, the second wall parts 55 are fixed to the inside of the frame part 51. Each of the second wall parts 55 may be a component independent of the frame part 51.

The second wall parts 55 form a plurality of second openings 57 arranged in substantially parallel with each other. The second openings 57 are examples of a plurality of first through holes. Each of the second openings 57 is a hexagonal hole extending in the direction along the Z-axis (vertical direction). In other words, the second wall parts 55 form an aggregate (honeycomb structure) of a plurality of hexagonal tubes in which the second opening 57 is formed. The second opening 57 extending in the direction along the Z-axis can allow passage of a substance such as the particle C moving in the direction along the Z-axis. The second opening 57 may be formed in another shape.

In a plan view in the direction along the Z-axis, the shape of the second opening 57 is substantially the same as that of the first opening 47. Additionally, in a plan view in the direction along the Z-axis, the second openings 57 are arranged at positions to be able to be overlapped with the first openings 47. The shape and the position of the second opening 57 may be different from the shape and the position of the first opening 47.

The collimation component 32 includes an upper end part 32a and a lower end part 32b. The upper end part 32a is one end of the collimation component 32 in the direction along the Z-axis, and faces the target 12 and the attachment face 21a of the upper wall 21. The lower end part 32b is the other end of the collimation component 32 in the direction along the Z-axis, and faces the semiconductor wafer 2 supported by the stage 13 and the placement face 13a of the stage 13.

The second opening 57 is arranged from the upper end part 32a to the lower end part 32b of the collimation component 32. That is, the second opening 57 is a hole that opens toward the target 12, and opens toward the semiconductor wafer 2 supported by the stage 13.

Each of the second wall parts 55 is a substantially rectangular (quadrangle) plate extending in the direction along the Z-axis. For example, the second wall part 55 may extend in a direction obliquely intersecting with the direction along the Z-axis. The second wall part 55 includes an upper end face 55a and a lower end face 55b.

The upper end face 55a of the second wall part 55 is one end of the second wall part 55 in the direction along the Z-axis, and faces the target 12 and the attachment face 21a of the upper wall 21. The upper end face 55a of each of the second wall parts 55 forms the upper end part 32a of the collimation component 32.

The upper end part 32a of the collimation component 32 is formed to be substantially flat. For example, the upper end part 32a may be depressed like a curved face with respect to the target 12 and the attachment face 21a of the upper wall 21. In other words, the upper end part 32a may be curved to be separated away from the target 12 and the attachment face 21a of the upper wall 21.

The lower end face 55b of the second wall part 55 is the other end of the second wall part 55 in the direction along the Z-axis, and faces the semiconductor wafer 2 supported by the stage 13 and the placement face 13a of the stage 13. The lower end face 55b of each of the second wall parts 55 forms the lower end part 32b of the collimation component 32.

The lower end part 32b of the collimation component 32 is formed to be substantially flat. For example, the lower end part 32b may project toward the semiconductor wafer 2 supported by the stage 13 and the placement face 13a of the stage 13. In other words, the lower end part 32b of the collimation component 32 may become closer to the stage 13 as being separated away from the frame part 51. The lower end part 32b of the collimation component 32 may be formed in another shape.

The upper end part 32a and the lower end part 32b of the collimation component 32 have substantially the same shape. Thus, the collimation component 32 includes a plurality of second wall parts 55 having substantially the same length in the vertical direction. The lengths of the second wall parts 55 may be different from each other in the direction along the Z-axis.

The length of the rectifying part 42 is longer than the length of the collimation component 32 in the direction along the Z-axis. The length of the rectifying part 42 is the maximum length between the upper end part 42a and the lower end part 42b in the direction along the Z-axis. The length of the collimation component 32 is a length between the upper end part 32a and the lower end part 32b in the direction along the Z-axis. The dimension of the collimation component 32 is not limited thereto.

A plurality of projecting parts 53 are arranged on the outer peripheral face 51b of the frame part 51. The projecting part 59 is an example of a second holding part. Each of the projecting parts 59 extends in the direction along the Z-axis. The projecting parts 59 extend from the upper end. part 32a to the lower end part 32b of the collimation component 32. The projecting part 59 may have another shape.

As illustrated in FIG. 2, the projecting parts 59 are arranged in a circumferential direction of the tubular frame part 51. The circumferential direction of the frame part 51 is a direction rotating about the center axis of the frame part 51. The projecting parts 59 are arranged on the entire outer peripheral face 51b of the frame part 51 in the circumferential direction of the frame part 51. For example, projecting parts 59 may be arranged at intervals in the circumferential direction of the frame part 51. One projecting part 59 may be arranged on the outer peripheral face 51b of the frame part 51.

The collimation component 32 is removably attached to the inside of the frame 41 of the base component 31. The collimation component 32 is attached to the inside of the frame 41 so that the frame part 51 is arranged concentrically with the frame 41. In other words, the center axis of the frame 41 and the center axis of the frame part 51 of the collimation component 32 attached to the frame 41 are arranged at substantially the same position.

For example, the collimation component 32 is inserted into the inside of the frame 41 so that the projecting parts 59 of the collimation component 32 are inserted into the grooves 49 of the frame 41. The projecting part 59 is inserted into the groove 49 through a portion of the groove 49 opening at the upper end 41c of the frame 41.

The projecting parts 59 of the collimation component 32 engage with the grooves 49 of the frame 41. Thus, when the collimation component 32 starts to rotate (relatively move) with respect to the frame 41 in the circumferential direction of the frame 41, the projecting part 59 is brought into contact with the frame 41 forming the groove 49. In this way, the groove 49 and the projecting part 59 limit rotation of the collimation component 32 with respect to the frame 41 in the circumferential direction of the frame 41.

As illustrated in FIG. 3, the collimation component 32 attached to the inside of the frame 41 is arranged side by side with the rectifying part 42 in the direction along the Z-axis. The collimation component 32 is positioned between the rectifying part 42 and the upper wall 21. The collimation component 32 is, for example, supported by the upper end part 42a of the rectifying part 42. The base component 31 may support the collimation component 32 at a portion different from the upper end part 42a of the rectifying part 42.

The upper end part 42a of the rectifying part 42 supports the collimation component 32, and limits movement (dropping) of the collimation component 32 in the negative direction along the Z-axis toward the stage 13. On the other hand, the collimation component 32 can move along the groove 49 in the positive direction along the Z-axis. The frame 41 may limit the movement of the collimation component 32 in the positive direction along the Z-axis.

In FIG. 2, the collimation component 32 is attached to the inside of the frame 41 at a first position P1 with respect to the frame 41. The first position P1 is an example of a first position, a third position, and a fifth position.

In a plan view in the direction along the Z-axis, the second openings 57 of the collimation component 32 positioned at the first position P1 are arranged at substantially the same positions as those of the first openings 47 of the rectifying part 42. Thus, the first openings 47 and the second openings 57 are connected to be continuous in the direction along the Z-axis.

In a plan view in the direction along the Z-axis, the second wall parts 55 of the collimation component 32 positioned at the first position P1 are arranged at substantially the same positions as those of the first wall parts 45 of the rectifying part 42. Thus, the first wall parts 45 and the second wall parts 55 are connected to be continuous in the direction along the Z-axis.

As illustrated in FIG. 3, an aspect ratio of the connected first and second openings 47 and 57 is determined depending on a width W1 and a height H1 of the connected first and second openings 47 and 57. In the present embodiment, the width W1 of the first and second openings 47 and 57 is the length of the first and second openings 47 and 57 in a direction along the X-axis. In the present embodiment, the height H1 of the first and second openings 47 and 57 is a length between the lower end part 42b of the rectifying part 42 and the upper end part 32a of the collimation component 32 in the direction along the Z-axis. An aspect ratio R1 in the example of FIG. 3 is H1/W1.

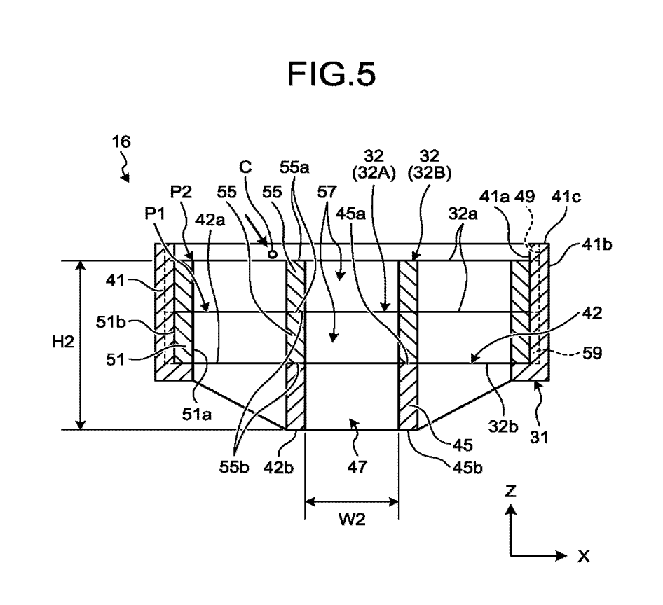

FIG. 5 is a cross-sectional view schematically illustrating the collimator 16 including two collimation components 32 according to the first embodiment. As illustrated in FIG. 5, the collimator 16 may include two collimation components 32. The collimator 16 may include three or more collimation components 32.

In the example of FIG. 5, the two collimation components 32 are removably attached to the inside of the frame 41. Hereinafter, one of the collimation components 32 is referred to as a collimation component 32A, and the other one thereof is referred to as a collimation component 32B. Explanation common to the collimation components 32A and 32B is described as explanation for the collimation component 32. The collimation component 32A and the collimation component 32B have the same shape.

The collimation component 32A is supported by the upper end face 42a of the rectifying part 42. The collimation component 32B is stacked on the collimation component 32A. The collimation component 32B is supported by the upper end part 32a of the collimation component 32A. The collimation component 32A is positioned between the rectifying part 42 and the collimation component 32B.

In the example of FIG. 5, the collimation component 32A is attached to the inside of the frame 41 at the first position P1 with respect to the frame 41. On the other hand, the collimation component 32B is closer to the upper wall 21 than the collimation component 32A positioned at the first position P1. In this way, the collimation component 32B is attached to the inside of the frame 41 at a second position P2 different from the first position P1. The second position P2 is an example of a sixth position.

Relative positions of the collimation component 32 (32B) and the frame 41 in the direction along the Z-axis at the second position P2 are different from relative positions of the collimation component 32 (32A) and the frame 41 in the direction along the Z-axis at the first position P1. The first position P1 and the second position P2 are the same except the position in the direction along the Z-axis.

In the example of FIG. 5, the first openings 47 of the rectifying part 42, the second openings 57 of the collimation component 32A, and the second openings 57 of the collimation component 32B are connected to be continuous in the direction along the Z-axis. The first wall parts 45 of the rectifying part 42, the second wall parts 55 of the collimation component 32A, and the second wall parts 55 of the collimation component 32B are connected to be continuous in the direction along the Z-axis.

The aspect ratio of the connected first and second openings 47 and 57 is determined depending on a width W2 and a height H2 of the connected first and second openings 47 and 57. In the present embodiment, the width W2 of the first and second openings 47 and 57 is the length of the first and second openings 47 and 57 in the direction along the X-axis. In the present embodiment, the height H2 of the first and second openings 47 and 57 is the length between the lower end part 42b of the rectifying part 42 and the upper end part 32a of the collimation component 32B in the direction along the Z-axis.

An aspect ratio R2 in the example of FIG. 5 is H2/W2. The height H2 is larger than the height H1. The width W2 is equal to the width W1. Thus, the aspect ratio R2 in FIG. 5 is larger than the aspect ratio R1 in FIG. 3.

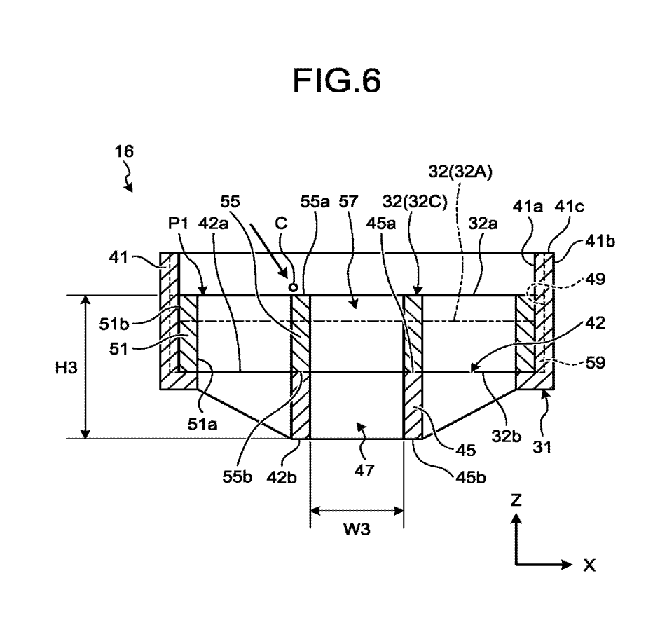

FIG. 6 is a cross-sectional view schematically illustrating the collimator 16 including a collimation component 32C according to the first embodiment. As illustrated in FIG. 6, the collimator 16 may include the collimation component 32C different from the collimation components 32A and 32B. FIG. 6 illustrates the collimation component 32A by a two-dot chain line.

In the direction along the Z-axis, the length of the collimation component 32C is longer than the length of the collimation component 32A. The length of the collimation component 32C is a length between the upper end part 32a and the lower end part 32b of the collimation component 32C in the direction along the Z-axis. In the direction along the Z-axis, the length of the collimation component 32C may be shorter than the length of the collimation component 32A. The collimation component 32C has the same shape as that of the collimation component 32A except the length in the direction along the Z-axis.

In the example of FIG. 6, the collimation component 32C is attached to the inside of the frame 41 at the first position P1 with respect to the frame 41. Thus, the first openings 47 of the rectifying part 42 and the second openings 57 of the collimation component 32C are connected to be continuous in the direction along the Z-axis. The first wall parts 45 of the rectifying part 42 and the second wall parts 55 of the collimation component 32C are connected to be continuous in the direction along the Z-axis.

The aspect ratio of the connected first and second openings 47 and 57 is determined depending on a width W3 and a height H3 of the connected first and second openings 47 and 57. In the present embodiment, the width W3 of the first and second openings 47 and 57 is the length of the first and second openings 47 and 57 in the direction along the X-axis. In the present embodiment, the height H3 of the first and second openings 47 and 57 is a length between the lower end part 42b of the rectifying part 42 and the upper end part 32a of the collimation component 32C in the direction along the Z-axis.

An aspect ratio R3 in the example of FIG. 6 is H3/W3. The height H3 is larger than the height H1. The width W3 is equal to the width W1. Thus, the aspect ratio R3 in FIG. 6 is larger than the aspect ratio R1 in FIG. 3.

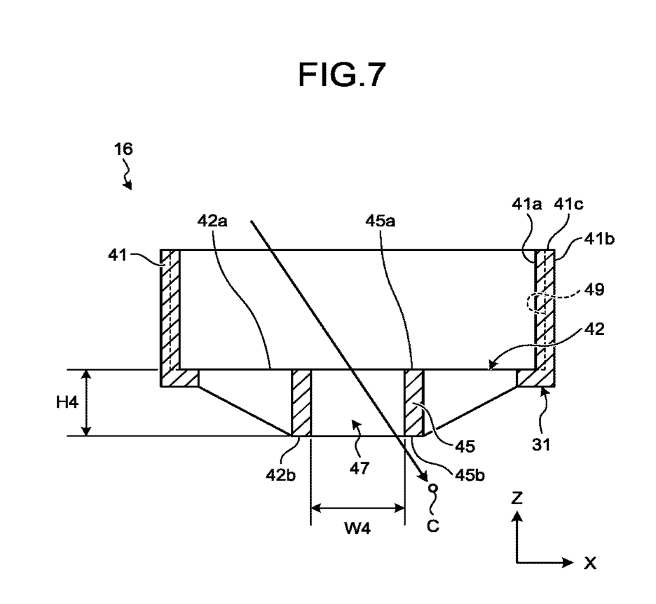

FIG. 7 is a cross-sectional view schematically illustrating the collimator 16 from which the collimation component 32 is removed according to the first embodiment. The collimation component 32 can be removed from the frame 41. In this case, the aspect ratio of the first opening 47 is determined depending on a width W4 and a height H4 of the first opening 47. In the present embodiment, the width W4 of the first opening 47 is the length of the first opening 47 in the direction along the X-axis. In the present embodiment, the height H4 of the first opening 47 is a length between the lower end part 42b and the upper end part 42a of the rectifying part 42 in the direction along the Z-axis.

An aspect ratio R4 in the example of FIG. 7 is H4/W4. The height H4 is smaller than the height H1. The width W4 is equal to the width W1. Thus, the aspect ratio R4 in FIG. 7 is smaller than the aspect ratio R1 in FIG. 3.

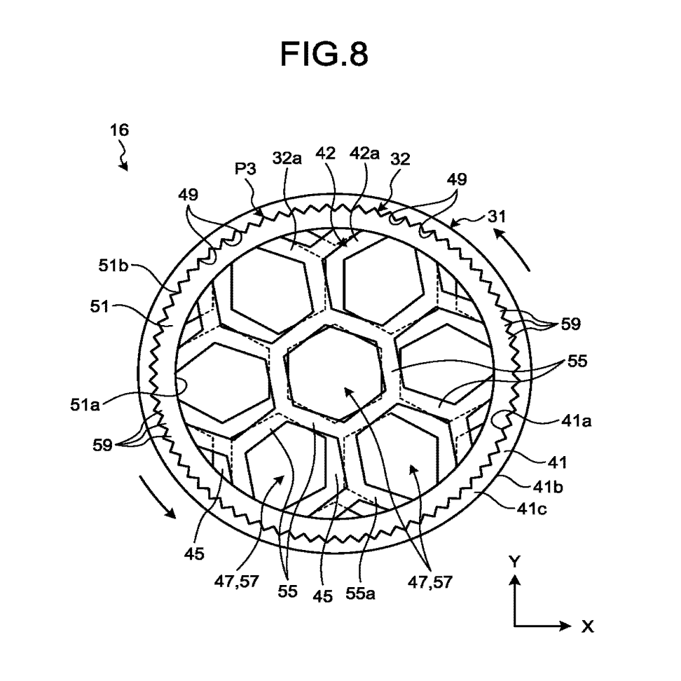

FIG. 8 is a plan view schematically illustrating the collimator 16 in which the collimation component 32 is rotated according to the first embodiment. As illustrated in FIG. 8, the collimation component 32 may be attached to the inside of the frame 41 at a third position P3 with respect to the frame 41. The third position P3 is an example of a fourth position.

The relative positions of the collimation component 32 and the frame 41 in the circumferential direction of the frame 41 at the third position P3 are different from the relative positions of the collimation component 32 and the frame 41 in the circumferential direction of the frame 41 at the first position P1. In other words, with respect to the relative positions of the collimation component 32 and the frame 41 at the first position P1, the collimation component 32 at the third position P3 is rotated by a predetermined angle with respect to the frame 41.

The collimation component 32 at the third position P3 is supported by the upper end part 42a of the rectifying part 42. That is, in the direction along the Z-axis, the position of the collimation component 32 at the third position P3 is substantially the same as the position of the collimation component 32 at the first position P1.

The positions of the second openings 57 at the third position P3 are different from the positions of the first openings 47. In a plan view in the direction along the Z-axis, the second opening 57 at the third position P3 is partially overlapped with the first opening 47. One second opening 57 may be partially overlapped with a plurality of first openings 47. The second opening 57 at the third position P3 is connected to the first opening 47 in the direction along the Z-axis.

The aspect ratio of the connected first and second openings 47 and 57 is determined depending on the width and the height of the connected first and second openings 47 and 57. In the present embodiment, the width of the first and second openings 47 and 57 is the length of the first and second openings 47 and 57 in the direction along the X-axis. In the present embodiment, the height of the first and second openings 47 and 57 is a length between the lower end part 42b of the rectifying part 42 and the upper end part 32a of the collimation component 32 in the direction along the Z-axis.

The height in the example of FIG. 8 is equal to the height H1. The width in the example of FIG. 8 may be smaller than the width W1 in some cases. Thus, an aspect ratio R5 in FIG. 8 may be larger than the aspect ratio R1 in FIG. 3 in some cases.

For example, the aspect ratio at the first position P1 of the first and second openings 47 and 57 positioned at the center portion of the collimator 16 is substantially equal to the aspect ratio thereof at the third position P3. On the other hand, the aspect ratio at the third position P3 of the first and second openings 47 and 57 positioned at a portion remote from the center of the collimator 16 is larger than the aspect ratio thereof at the first position P1.

The sputtering device 1 described above performs, for example, magnetron sputtering as follows. A method of performing magnetron sputtering by the sputtering device 1 is not limited to the method described below.

First, the pump 17 illustrated in FIG. 1 sucks the gas in the processing chamber 11a through the ejection port 24. Accordingly, air in the processing chamber 11a is removed, and the air pressure in the processing chamber 11a is lowered. The pump 17 evacuates the processing chamber 11a.

Next, the tank 18 introduces the argon gas into the processing chamber 11a from the introduction port 25. When voltage is applied to the target 12, the plasma P is generated near a magnetic field of the magnet 14. Additionally, the voltage may be applied to the stage 13.

When the lower face 12a of the target 12 is sputtered with the ion, the particle C is emitted from the lower face 12a of the target 12 toward the semiconductor wafer 2. As described above, the directions in which the particles C fly are distributed in accordance with the cosine law.

In the example of FIG. 3, the particle C emitted in the vertical direction passes through the first and second openings 47 and 57, and flies toward the semiconductor wafer 2 supported by the stage 13. On the other hand, some particles C are emitted in a direction obliquely intersecting with the vertical direction (inclined direction).

The particle C having an angle between the inclined direction and the vertical direction being outside a predetermined range adheres to the collimator 16. For example, the particle C adheres to the first wall part 45 or the second wall part 55. That is, the collimator 16 blocks the particle C having an angle between the inclined direction and the vertical direction being outside the predetermined range. The particle C flying in the inclined direction may adhere to the shielding member 15.

The particle C having an angle between the inclined direction and the vertical direction within the predetermined range passes through the first and second openings 47 and 57 of the collimator 16, and flies toward the semiconductor wafer 2 supported by the stage 13. The particle C having an angle between the inclined direction and the vertical direction within the predetermined range may adhere to the shielding member 15 or the collimator 16.

The particle C that has passed through the first and second openings 47 and 57 of the collimator 16 adheres to or is piled up on the semiconductor wafer 2 to be deposited on the semiconductor wafer 2. In other words, the semiconductor wafer 2 receives the particle C emitted from the target 12. Orientations (directions) of the particles C that have passed through the first and second openings 47 and 57 are aligned within a predetermined range with respect to the vertical direction. In this way, the direction of the particle C deposited on the semiconductor wafer 2 is controlled depending on the shape of the collimator 16.

The magnet 14 moves until a thickness of a film of the particles C deposited on the semiconductor wafer 2 reaches a desired thickness. The plasma P moves along with the movement of the magnet 14, and the target 12 can be uniformly shaved.

The angle (collimation angle) between the inclined direction and the vertical direction of the particle C that can pass through the collimator 16 varies depending on the aspect ratio of the first and second openings 47 and 57. The collimation angle is reduced as the aspect ratio of the first and second openings 47 and 57 is set to be large, and the orientations (directions) of the particles C deposited on the semiconductor wafer 2 are aligned more accurately.

For example, the collimation angle of the collimator 16 in the example of FIG. 5 having the aspect ratio of R2 is smaller than the collimation angle of the collimator 16 in the example of FIG. 3 having the aspect ratio of R1. Thus, the orientations of the particles C deposited on the semiconductor wafer 2 in the example of FIG. 5 are aligned more accurately than the orientations of the particles C deposited on the semiconductor wafer 2 in the example of FIG. 3.

The collimation angle of the collimator 16 in the example of FIG. 6 having the aspect ratio of R3 is smaller than the collimation angle of the collimator 16 in the example of FIG. 3 having the aspect ratio of R1. Thus, the orientations of the particles C deposited on the semiconductor wafer 2 in the example of FIG. 6 are aligned more accurately than the orientations of the particles C deposited on the semiconductor wafer 2 in the example of FIG. 3.

In the collimator 16 in the example of FIG. 8, the collimation angles of the first and second openings 47 and 57 are different from each other. The collimation angle of each of the first and second openings 47 and 57 in the center portion of the collimator 16 is substantially equal to the collimation angle of the collimator 16 in the example of FIG. 3 having the aspect ratio of R1. The collimation angle of each of the first and second openings 47 and 57 positioned at a portion remote from the center of the collimator 16 is smaller than the collimation angle of the collimator 16 in the example of FIG. 3.

In a certain example, many particles C fly vertically toward the semiconductor wafer 2 at the center portion of the collimator 16. Thus, the orientations of the particles C are sufficiently aligned, the particles C passing through the first and second openings 47 and 57 having substantially the same aspect ratio as that in the example of FIG. 3.

On the other hand, in the portion remote from the center of the collimator 16, a small number of particles C fly vertically toward the semiconductor wafer 2, and many particles C fly obliquely. These particles C pass through the first and second openings 47 and 57 having the aspect ratio higher than that in the example of FIG. 3, so that the orientations of the particles C are aligned more accurately than the example of FIG. 3.

As described above, the aspect ratio of the collimator 16 in the example of FIG. 8 is set to be large in a portion in which many particles C fly obliquely. Thus, the orientations of the particles C deposited on the semiconductor wafer 2 are aligned more accurately than the orientations of the particles C deposited on the semiconductor wafer 2 in the example of FIG. 3.

As described above, when the collimator 16 is set as in the example of FIG. 5, FIG. 6, or FIG. 8, the orientations of the particles C deposited on the semiconductor wafer 2 are aligned more accurately. For example, to align the orientations of the particles C deposited on the semiconductor wafer 2 more accurately, as illustrated in FIG. 5, the collimation component 32B is added to the collimator 16.

The examples of the FIG. 5, FIG. 6, and FIG. 8 may be combined with each other. For example, the collimation component 32C may be stacked on the collimation component 32A. The stacked collimation components 32A and 32B may be rotated with respect to the frame 41.

On the other hand, the collimation angle of the collimator 16 in the example of FIG. 7 having the aspect ratio of R4 is larger than the collimation angle of the collimator 16 in the example of FIG. 3 having the aspect ratio of R1. Thus, the orientations of the particle C deposited on the semiconductor wafer 2 in the example of FIG. 7 fluctuate more than the orientations of the particles C deposited on the semiconductor wafer 2 in the example of FIG. 3.

For example, when the orientations of the particles C deposited on the semiconductor wafer 2 allow predetermined fluctuation, the collimation component 32 may be removed from the collimator 16 as illustrated in FIG. 7. Also in the example of FIG. 7, the directions of the particles C deposited on the semiconductor wafer 2 are controlled by the rectifying part 42 of the collimator 16.

As described above, when the collimation component 32 is changed as in the examples of FIGS. 5 to 8, a range of the orientations of the particles C deposited on the semiconductor wafer 2 is changed. The collimation component 32 is attached to the frame 41 of the base component 31 at a desired position before magnetron sputtering is performed, or removed from the frame 41.

The base component 31 and the collimation component 32 of the collimator 16 according to the present embodiment are additive-manufactured with a 3D printer, for example. The base component 31 and the collimation component 32 may be manufactured by using another method such as casting and forging.

In the sputtering device 1 according to the first embodiment, the collimator 16 includes the frame 41 and the collimation component 32 configured to be removably attached to the inside of the frame 41. The collimation component 32 includes a plurality of second wall parts 55, and includes a plurality of second openings 57 extending in the direction along the Z-axis arranged with the second wall parts 55. In the collimator 16, the collimation components 32 (32A, 32B, and 32C) having various shapes can be attached to the frame 41 in accordance with a condition. For example, the angle of the particle C deposited on the semiconductor wafer 2 is strictly limited, the collimation component 32C in which the aspect ratio of the second opening 57 is high is attached to the frame 41. Accordingly, the range of the direction (angle) of the particle C passing through the collimator 16 can be adjusted without making another collimator 16. The aspect ratio of the collimator 16 is adjusted before sputtering, so that dust is prevented from being generated during sputtering.

The rectifying part 42 including a plurality of first wall parts 45 is fixed to the inside of the frame 41 to be arranged side by side with the collimation component 32 in the direction along the Z-axis. Accordingly, a plurality of second openings 57 of the collimation component 32 and a plurality of first openings 47 of the rectifying part 42 can be connected in the direction along the Z-axis. When the second opening 57 is connected to the first opening 47, the aspect ratio of the connected first and second openings 47 and 57, which are through holes through which the particle C passes, can foe set in accordance with a condition. That is, the range of the direction (angle) of the particle C passing through the collimator 16 can be adjusted. The rectifying part 42 is fixed to the frame 41, so that the collimator 16 can limit the angle of the particle C deposited on the semiconductor wafer 2 in a state in which the collimation component 32 is not attached to the frame 41.

The collimation component 32 can be attached to the inside of the frame 41 at a plurality of positions with respect to the frame 41. For example, the collimation component 32 can be attached to the inside of the frame 41 at the first position P1 and the second position P2, a distance between the upper wall 21 and the upper end face 55a of the second wall part 55 of the collimation component 32 being different between the first position P1 and the second position P2. Due to this, an angle at which the particle C can pass through the second opening 57 is changed. That is, the range of the direction (angle) of the particle C passing through the collimator 16 can be adjusted. For example, the collimation component 32 can be attached to the inside of the frame 41 at the first position P1 and the second position P2, a distance between the upper end face 55a of the second wall part 55 of the collimation component 32 (32B) and the first wall part 45 of the rectifying part 42 being different between the first position P1 and the second position P2. By changing such a position at which the collimation component 32 is attached to the frame 41, the aspect ratio of the first and second openings 47 and 57 can be changed. In this way, by changing the position of the collimation component 32 with respect to the frame 41, the range of the direction (angle) of the particle C passing through the collimator 16 can be adjusted.

The relative positions of the collimation component 32 and the frame 41 in the circumferential direction of the frame 41 at the first position P1 are different from the relative positions of the collimation component 32 and the frame 41 in the circumferential direction of the frame 41 at the third position P3. That is, the relative positions of the second opening 57 and the first opening 47 at the first position P1 are different from the relative positions of the second opening 57 and the first opening 47 at the third position P3. Accordingly, the aspect ratio of the connected first and second openings 47 and 57 can be set in accordance with a condition. That is, the range of the direction (angle) of the particle C passing through the collimator 16 can be adjusted.

The relative positions of the collimation component 32 and the frame 41 in the direction along the Z-axis at the first position P1 are different from the relative positions of the collimation component 32 (32B) and the frame 41 in the direction along the Z-axis at the second position P2. That is, in the direction along the Z-axis, the height H1 of the first and second openings 47 and 57 at the first position P1 is different from the height H2 of the first and second openings 47 and 57 at the second position P2. Accordingly, the aspect ratio of the connected first and second openings 47 and 57 can be set in accordance with a condition. That is, the range of the direction (angle) of the particle C passing through the collimator 16 can be adjusted.

The groove 49 and the projecting part 59 engage with each other, and are brought into contact with each other when the collimation component 32 moves in the circumferential direction of the frame 41 with respect to the frame 41. Due to this, the collimation component 32 can be prevented from undesirably rotating with respect to the frame 41. Accordingly, the aspect ratio of the first and second openings 47 and 57 through which the particle C passes is prevented from being changed, for example, during processing such as sputtering.

A plurality of collimation components 32A and 32B are configured to be removably attached to the inside of the frame 41. In the collimator 16, the number of the collimation components 32 can be set in accordance with a condition. For example, the angle of the particle C deposited on the semiconductor wafer 2 is strictly limited, a large number of collimation components 32 are attached to the frame 41. Due to this, the aspect ratio of the second openings 57 to be connected is increased. Accordingly, the range of the direction (angle) of the particle C passing through the collimator 16 can be adjusted without making another collimator 16.

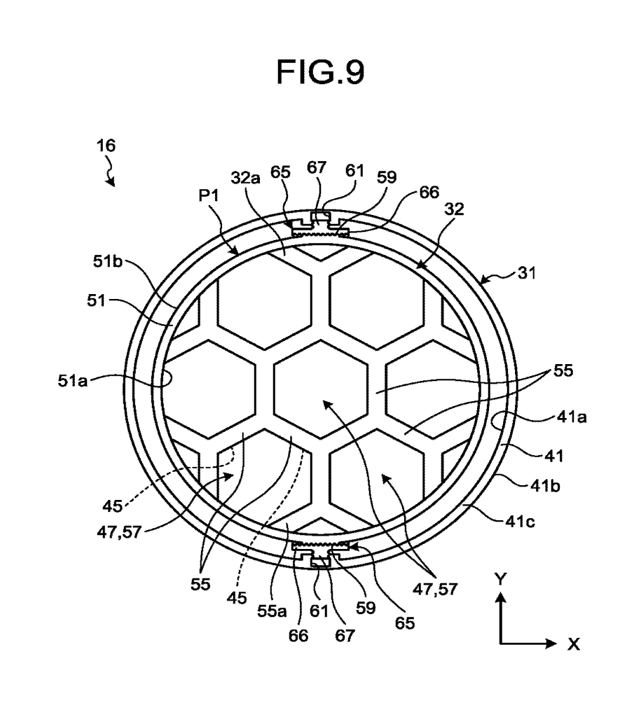

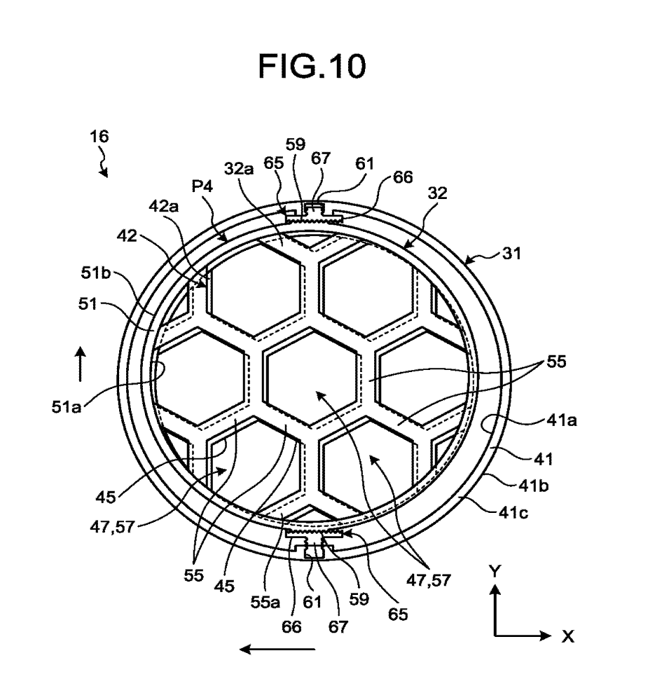

The following describes a second embodiment with reference to FIGS. 9 and 10. In the following description of a plurality of embodiments, a component having the same function as that of the component already discussed may be denoted by the same reference numeral as that of the component already discussed, and redundant description will not be repeated in some cases. A plurality of components denoted by the same reference numeral do not necessarily have the same function and the same property, and may have different functions and properties depending on the embodiments.

FIG. 9 is a plan view schematically illustrating the collimator 16 according to the second embodiment. As illustrated in FIG. 9, in the second embodiment, the projecting parts 59 of the collimation component 32 are arranged on both ends of the frame part 51 in a direction along the Y-axis. The projecting parts 59 according to the second embodiment are arranged in the direction along the X-axis, and projects from the outer peripheral face 51a in the direction along the Y-axis.

Two holding grooves 61 are arranged on the frame 41 according to the second embodiment in place of the grooves 49. The two holding grooves 61 are arranged on both ends of the frame 41 in the direction along the Y-axis. The holding groove 61 is arranged on the inner peripheral face 41a of the frame 41, and extends in the direction along the Z-axis. The holding groove 61 extends from the upper end part 42a of the rectifying part 42 to the upper end 41c of the frame 41.

A plurality of projections arranged in the direction along the Y-axis are formed on an inner face of the holding groove 61 facing the direction along the X-axis. The projections are arranged on both of two inner faces of the holding groove 61 facing the direction along the X-axis. Alternatively, the projections may be arranged on one of the two inner faces. The projections also extend in the direction along the Z-axis.

The base component 31 according to the second embodiment includes two holding members 65. The holding member 65 includes a first engagement part 66 and a second engagement part 67. The first engagement part 66 is an example of a first holding part.

The first engagement part 66 extends in the direction along the X-axis. A plurality of projections are formed on the first engagement part 66, the projections projecting toward the frame 41 of the collimation component 32 and arranged in the direction along the X-axis. The projection extends in the direction along the Z-axis.

The first engagement part 66 on which the projections are formed engages with the projecting parts 59 of the collimation component 32. Thus, when the collimation component 32 starts to move in the direction along the X-axis with respect to the frame 41, the projecting part 59 is brought into contact with the projection of the first engagement part 66. In this way, the projecting part 59 and the first engagement part 66 limit the movement of the collimation component 32 in the direction along the X-axis with respect to the frame 41.

When the collimation component 32 starts to move with respect to the frame 41 in the circumferential direction of the frame 41, the projecting part 59 is brought into contact with the projection of the first engagement part 66. In this way, the projecting part 59 and the first engagement part 66 limits the movement of the collimation component 32 with respect to the frame 41 in the circumferential direction of the frame 41.

The second engagement part 67 extends in the direction along the Y-axis from the first engagement part 66. The second engagement part 67 is inserted into the holding groove 61. A plurality of projections are formed on the second engagement part 67, the projections projecting in the direction along the X-axis and arranged in the direction along the Y-axis. The projection extends in the direction along the Z-axis.

The second engagement part 67 on which the projections are formed engages with the holding groove 61 on which the projections are formed. Due to this, when the holding member 65 starts to move with respect to the frame 41 in the direction along the Y-axis, the projection of the holding groove 61 is brought into contact with the projection of the second engagement part 67. In this way, the holding groove 61 and the second engagement part 67 limit the movement of the holding member 65 with respect to the frame 41 in the direction along the Y-axis.

The holding member 65 holds the collimation component 32 on the frame 41 in the direction along the X-axis. The holding member 65 holding the collimation component 32 is held by the frame 41 in the direction along the Y-axis. Accordingly, the collimation component 32 is held by the frame 41 in the direction along the X-axis and the direction along the Y-axis. As described above, the collimation component 32 may be attached to the inside of the frame 41 at a position separated from the inner peripheral face 41a of the frame 41.

In the example of FIG. 9, the collimation component 32 is attached to the inside of the frame 41 at the first position P1 with respect to the frame 41. Thus, the first openings 47 and the second openings 57 are connected to be continuous in the direction along the Z-axis.

FIG. 10 is a plan view schematically illustrating the collimator 16 in which the collimation component 32 is moved according to the second embodiment. As illustrated in FIG. 10, the collimation component 32 may be attached to the inside of the frame 41 at a fourth position P4 with respect to the frame 41. The fourth position P4 is an example of a second position.

The relative positions of the collimation component 32 and the frame 41 in the direction along the X-axis and the direction along the Y-axis at the fourth position P4 are different from the relative positions of the collimation component 32 and the frame 41 in the direction along the X-axis and the direction along the Y-axis at the first position P1. Each of the direction along the X-axis and the direction along the Y-axis is an example of a second direction.

For example, the collimation component 32 at the fourth position P4 is held by the holding member 65 at a position moved from the first position P1 in a negative direction along the X-axis (left direction in FIG. 10) with respect to the frame 41. The holding member 65 holding the collimation component 32 at the fourth position P4 is held by the holding groove 61 at a position moved from the first position PI in a positive direction along the Y-axis (upward direction in FIG. 10) with respect to the frame 41.

The collimation component 32 at the fourth position P4 is supported by the upper end part 42a of the rectifying part 42. That is, in the direction along the Z-axis, the position of the collimation component 32 at the fourth position P4 is substantially the same as the position of the collimation component 32 at the first position P1.

The positions of the second openings 57 at the fourth position P4 are different from the positions of the first openings 47. In a plan view in the direction along the Z-axis, the second opening 57 at the fourth position P4 is partially overlapped with the first opening 47. One second opening 57 may be partially overlapped with a plurality of first openings 47. The second opening 57 at the fourth position P4 is connected to the first opening 47 in the direction along the Z-axis.

The aspect ratio of the connected first and second openings 47 and 57 is determined depending on the width and the height of the connected first and second openings 47 and 57. In the present embodiment, the width of the first and second openings 47 and 57 is the length of the first and second openings 47 and 57 in the direction along the X-axis. In the present embodiment, the height of the first and second openings 47 and 57 is a length between the lower end part 42b of the rectifying part 42 and the upper end part 32a of the collimation component 32 in the direction along the Z-axis.

The height in the example of FIG. 10 is equal to the height H1. The width in the example of FIG. 10 is smaller than the width W1. Thus, an aspect ratio R6 in FIG. 10 is larger than the aspect ratio R1 in FIG. 9.

When the collimation component 32 is moved in the direction along the X-axis and the direction along the Y-axis, a plurality of first and second openings 47 and 57 having different aspect ratios may be formed. The collimation component 32 can be arranged at a position where such a plurality of first and second openings 47 and 57 are formed in accordance with a condition.

In the sputtering device 1 according to the second embodiment, the relative positions of the collimation component 32 and the frame 41 in the direction along the X-axis and the direction along the Y-axis at the first position P1 are different from the relative positions of the collimation component 32 and the frame 41 in the direction along the X-axis and the direction along the Y-axis at the fourth position P4. That is, the relative positions of the first and second openings 47 and 57 at the first position P1 are different from the relative positions of the first and second openings 47 and 57 at the fourth position P. Accordingly, the aspect ratio of the connected first and second openings 47 and 57 can be set in accordance with a condition. That is, the range of the direction (angle) of the particle C passing through the collimator 16 can be adjusted.

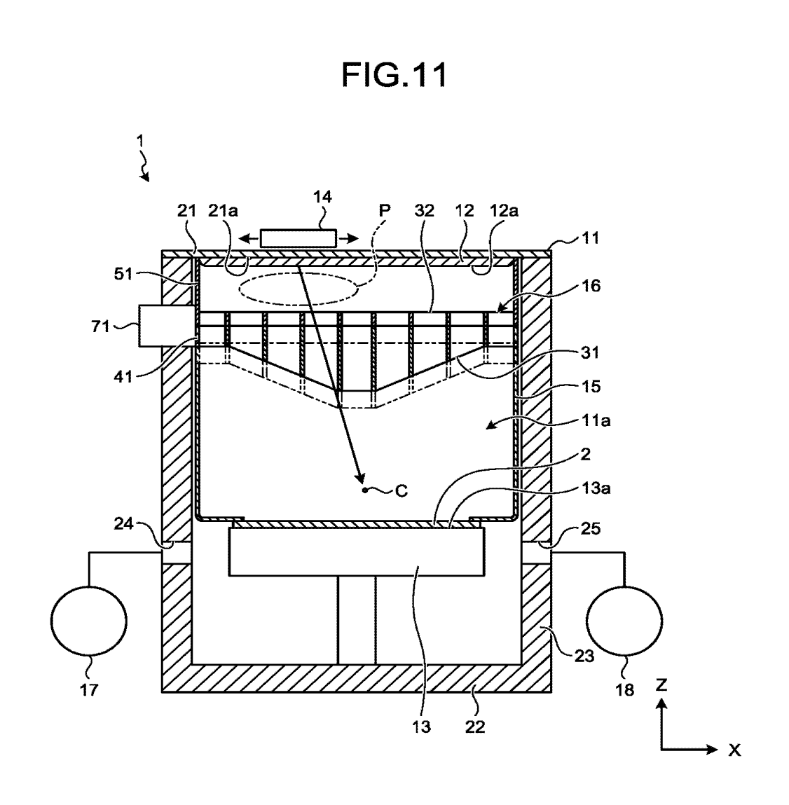

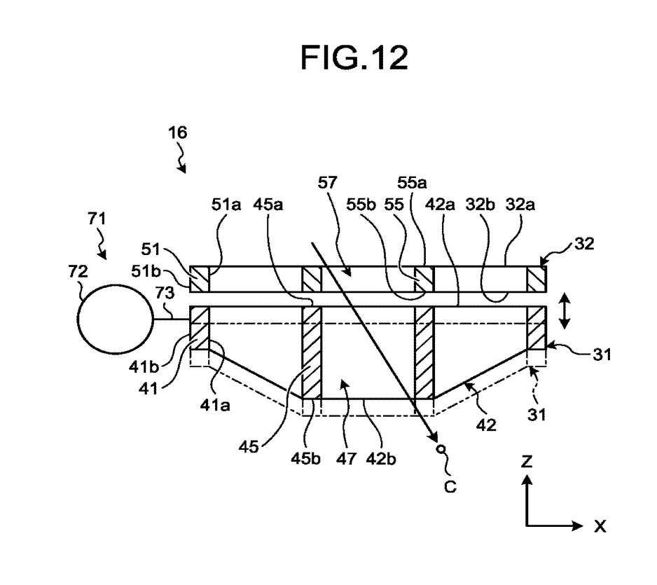

The following describes a third embodiment with reference to FIGS. 11 and 12. FIG. 11 is a cross-sectional view schematically illustrating the sputtering device 1 according to the third embodiment. As illustrated in FIG. 11, in the third embodiment, the collimation component 32 is separably connected to the base component 31.

FIG. 12 is a cross-sectional view schematically illustrating the collimator 16 according to the third embodiment. As illustrated in FIG. 12, the frame 41 of the base component 31 is arranged side by side with the frame part 51 of the collimation component 32 in the direction along the Z-axis.

The inner peripheral face 41a of the frame 41 and the inner peripheral face 51a of the frame part 51 can be connected to be continuous in the direction along the Z-axis. The outer peripheral face 41b of the frame 41 and the outer peripheral face 51b of the frame part 51 can be connected to be continuous in the direction along the Z-axis. The frame part 51 may be arranged inside the frame 41 similarly to the first embodiment.

The sputtering device 1 according to the third embodiment includes a driving unit 71. The driving unit 71 includes, for example, an actuator 72 and a driving mechanism 73. The actuator 72 is, for example, a servomotor. The actuator 72 may be another actuator such as a solenoid. The driving mechanism 73 connects the actuator 72 to the base component 31. The driving mechanism 73 may connect the actuator 72 to the collimation component 32. The driving mechanism 73 includes various components for transmitting power such as a gear, a rack, and a link mechanism.

As illustrated by a two-dot chain line in FIG. 12, the actuator 72 can move the base component 31 via the driving mechanism 73. In the present embodiment, the actuator 72 moves the base component 31 in the direction along the Z-axis via the driving mechanism 73. The actuator 72 may move the collimation component 32 in the direction along the Z-axis.

When the actuator 72 moves the base component 31, the relative positions of the base component 31 and the collimation component 32 are adjusted. That is, the collimation component 32 can be arranged at a plurality of positions with respect to the base component 31. Accordingly, the aspect ratio of the first and second openings 47 and 57 are adjusted, and the range of the direction (angle) of the particle C passing through the collimator 16 can be adjusted.

In the sputtering device 1 according to the third embodiment, the driving unit 71 changes the relative positions of the base component 31 and the collimation component 32. Accordingly, the relative positions of the base component 31 and the collimation component 32 can be easily changed.

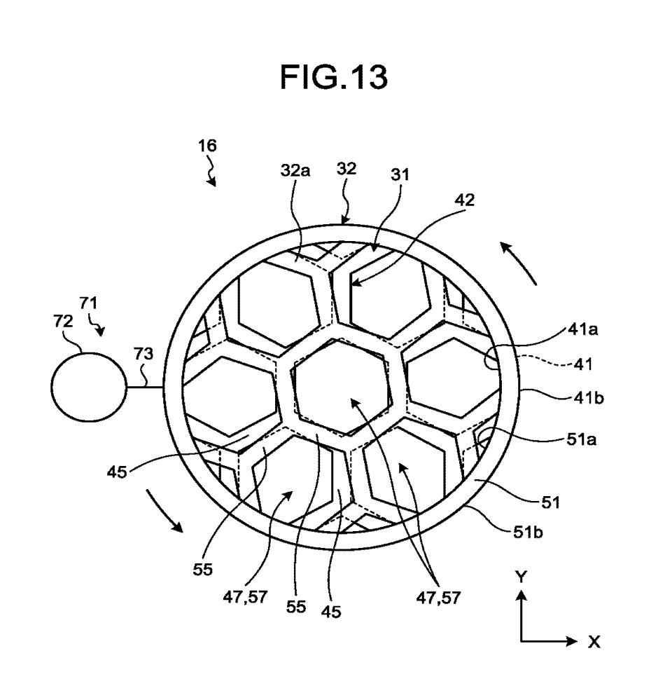

FIG. 13 is a plan view schematically illustrating the collimator 16 according to a first modification of the third embodiment. As illustrated in FIG. 13, the actuator 72 moves the base component 31 in the circumferential direction of the frame 41 via the driving mechanism 73. The actuator 72 may move the collimation component 32 in the circumferential direction of the frame 41.

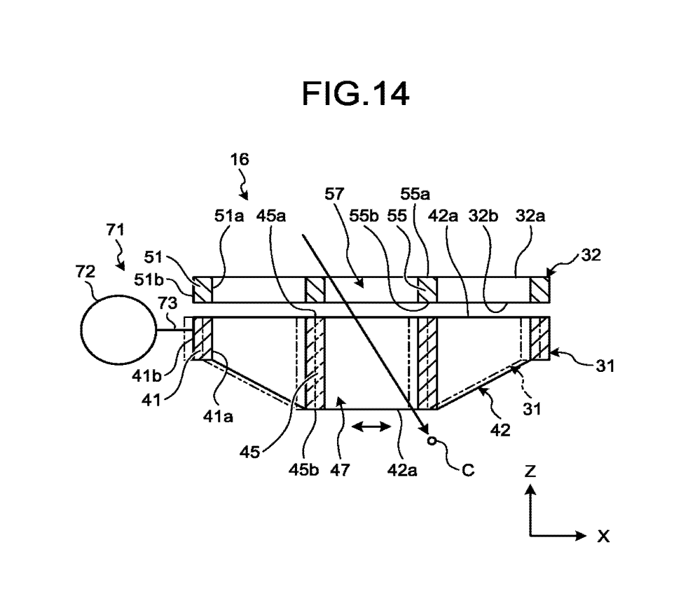

FIG. 14 is a cross-sectional view schematically illustrating the collimator 16 according to a second modification of the third embodiment. As illustrated by a two-dot chain line in FIG. 14, the actuator 72 moves the base component 31 in the direction along the X-axis and the direction along the Y-axis via the driving mechanism 73. The actuator 72 may move the collimation component 32 in the direction along the X-axis and the direction along the Y-axis.

When the collimation component 32 is moved in the direction along the X-axis and the direction along the Y-axis, a plurality of first and second openings 47 and 57 having different aspect ratios may be formed. In this case, the actuator 72 may integrally rotate the base component 31 and the collimation component 32 during sputtering. This configuration reduces fluctuation in the orientations of the particles C deposited on the semiconductor wafer 2.

In at least one of the embodiments described above, the sputtering device 1 is an example of a processing device. However, the processing device may be another device such as a vapor deposition device or an X-ray CT device.

When the processing device is the vapor deposition device, for example, a material to be vaporized is an example of the particle generating source, vapor generated from the material is an example of the particle, and a processing object to be vapor-deposited is an example of the substance. The vapor as a vaporized substance includes one type or a plurality of types of molecules. The molecule is the particle. In the vapor deposition device, for example, the collimator 16 is arranged between a position where the material to be vaporized is arranged and a position where the processing object is arranged.

When the processing device is the X-ray CT device, for example, an X-ray tube emitting X-rays is an example of the particle generating source, the X-ray is an example of the particle, and a subject irradiated with the X-ray is an example of the substance. The X-ray is a kind of an electromagnetic wave, and the electromagnetic wave is microscopically assumed to be a photon as a kind of an elementary particle. The elementary particle is the particle. In the X-ray CT device, for example, the collimator 16 is arranged between a position where the X-ray tube is arranged and a position where the subject is arranged.

In the X-ray CT device, an amount of X-rays emitted from the X-ray tube is not uniform in an irradiation range. By arranging the collimator 16 in such an X-ray CT device, the amount of X-rays in the irradiation range can be uniformized, and the irradiation range can be adjusted. Additionally, unnecessary exposure can be prevented.

In the embodiments described above, the collimation component 32 includes the frame part 51. However, the collimation component 32 does not necessarily include the frame part 51. The second wall parts 55 may be separable from each other. Each of the second wall parts 55 may be removably attached to the inside of the frame 41 independently.

According to at least one of the embodiments described above, the first rectifying part of the collimator is configured to be removably attached to the frame. This configuration can adjust the range of the direction of the particle passing through the collimator 16. A member to which the first rectifying part is attached does not necessarily have a frame shape, and may have another shape. For example, the first rectifying part may be removably attached to a plurality of members that can hold the first rectifying part therebetween.

The embodiments of the present invention have been described above. However, these embodiments are merely examples, and do not intend to limit the scope of the invention. These novel embodiments can be implemented in various other forms, and can be variously omitted, replaced, and modified without departing from the gist of the present invention. These embodiments and the modifications thereof are included in the scope and the gist of the present invention, and also included in the invention described in Claims and an equivalent thereof.

1. A processing device comprising:
a substance arrangement part on which a substance is arranged;
a generating source arrangement part arranged at a position separated away from the substance arrangement part, generating source that is able to emit a particle to the substance is arranged; and
a collimator configured to be arranged between the substance arrangement part and the generating source arrangement part, the collimator including: a frame; and a first rectifying part that includes a plurality of first walls and a plurality of first through holes formed with the first walls and extending in a first direction from the arrangement part, the collimator configured to be removably attached to the frame.

2. The processing device according to claim 1, wherein the collimator comprises a second rectifying part that includes a plurality of second walls and a plurality of second through holes formed with the second walls and extending in the first direction, the second rectifying part being fixed to the frame and configured to be arranged side by side with the first rectifying part in the first direction.

3. The processing device according to claim 2, wherein the first rectifying part is able to be attached to the frame at a plurality of positions with respect to the frame.

4. The processing device according to claim 3, wherein
the first rectifying part is able to be attached to the frame at a first position and a second position, and
relative positions of the first rectifying part and the frame in a second direction orthogonal to the first direction at the first position are different from relative positions of the first rectifying part and the frame in the second direction at the second position.

5. The processing device according to claim 3, wherein
the first rectifying part is able to be attached to the frame at a third position and a fourth position, and
relative positions of the first rectifying part and the frame in a circumferential direction of the frame at the third position are different from relative positions of the first rectifying part and the frame in the fourth position.

6. The processing device according to claim 3, wherein
the first rectifying part is able to be attached to the frame at a fifth position and a sixth position, and
relative positions of the first rectifying part and the frame in the first direction at the fifth position are different from relative positions of the first rectifying part and the frame in the first direction at the sixth position.

7. The processing device according to claim 1, wherein
the frame includes a first holding part,
the first rectifying part includes a second holding part, and
the first holding part is configured to be brought into contact with the second holding part of the first rectifying part that moves relatively to the frame in a circumferential direction of the frame.

8. The processing device according to claim 1, wherein
the collimator includes a plurality of the first rectifying parts, and
the first rectifying parts are configured to be removably attached to the frame.

9. A collimator comprising:
a frame; and
a first rectifying part configured to be removably attached to the frame, the first rectifying part including a plurality of first walls and a plurality of first through holes that are formed with the first walls and extend in a first direction.

10. The collimator according to claim 9, further comprising:
a second rectifying part that includes a plurality of second walls and a plurality of second through holes formed with the second walls and extending in the first direction, the second rectifying part being fixed to the frame and configured to be arranged side by side with the first rectifying part in the first direction.

11. The collimator according to claim 10, wherein the first rectifying part is able to be attached to the frame at a plurality of positons with respect to the frame.

12. The collimator according to claim 11, wherein
the first rectifying part is able to be attached to the frame at a first position and a second position, and
relative positions of the first rectifying part and the frame in a second direction orthogonal to the first positions of the first rectifying part and the frame in the second direction at the second position.

13. The collimator according to claim 11, wherein
the first rectifying part is able to be attached to the frame at a third position and a fourth position, and
relative positions of the first rectifying part and the frame in a circumferential direction of the frame at the third position are different from relative positions of the first rectifying part and the frame in the circumferential direction of the frame at the fourth position.

14. The collimator according to claim 11, wherein
the first rectifying part is able to be attached to the frame at a fifth position and a sixth position, and
relative positions of the first rectifying part and the frame in the first direction at the fifth position are different from relative positions of the first rectifying part and the frame in the first direction at the sixth position.

15. The collimator according to claim 9, wherein
the frame includes a first holding part,
the first rectifying part includes a second holding part, and
the first holding part is configured to be brought into contact with the second holding part of the first rectifying part that moves relatively to the frame in a circumferential direction of the frame.

16. The collimator according to claim 9, further comprising:
a plurality of the first rectifying parts, wherein
the first rectifying parts are configured to be able to be removably attached to the frame.
